(19) United States
(12) Patent Application Publication
(10) Pub. No.: US 2023/0411172 A1
(43) Pub. Date: Dec. 21, 2023

(54) CLEANED PACKAGING SUBSTRATE AND CLEANED PACKAGING SUBSTRATE MANUFACTURING METHOD

(71) Applicant: Absolics Inc., (US)

(72) Inventor: Sungjin KIM, Covington, GA (US)

(73) Assignee: Absolics Inc., Covington, GA (US)

(21) Appl. No.: 18/013,360

(22) PCT Filed: Sep. 7, 2022
(86) PCT No.: PCT/US2022/042677

§ 371 Date: Dec. 28, 2022

Related U.S. Application Data
(60) Provisional application No. 63/242,619, filed on Sep. 10, 2021.

(51) Int. Cl. H01L 21/48; B08B 5/02

(52) U.S. Cl. CPC H01L 21/4864; B08B 5/02

(57) ABSTRACT

A manufacturing method for a cleaned packaging substrate is provided. The method is applied to a manufacturing process for a glass substrate or a packaging substrate comprising the same, and comprises a preparing process of disposing a target substrate inside a chamber; and a removing process of jetting ionized air on at least one surface of the target substrate to separate particle impurities, and manufacturing a cleaned packaging substrate. The target substrate is a glass packaging substrate, or a packaging substrate, and the packaging substrate comprises the glass packaging substrate and a redistribution layer disposed on at least one surface of the glass packaging substrate.

### CROSS-REFERENCE TO RELATED APPLICATIONS

This application claims the priority of U.S. Provisional Patent Application No. 63/242,619, filed Sep. 10, 2021, the entire disclosures of which are incorporated herein by reference for all purposes.

### BACKGROUND

### 1. Field

The following description relates to a cleaned packaging substrate manufacturing method and a cleaned packaging substrate.

### 2. Description of Related Art

In the manufacturing of electronic components, the implementation of a circuit on a semiconductor wafer is referred to as a Front-End Process (FE), and the assembly of a wafer such that it can be actually used in a product is referred to as a Back-End Process (BE). The Back-End process may include a packaging process.

Recently, four key technologies of the semiconductor industry that enable the rapid development of electronic products include semiconductor technology, semiconductor packaging technology, manufacturing process technology, and software technology. Semiconductor technology has been developed in various forms such as line width of a nanometer unit, which is smaller than a micrometer unit, 10 million or more cells, and may result in high-speed operation, and may achieve heat dissipation, but may not be completely supported by packaging technology. Thus, it is considered that the electrical performance of packaged semiconductors may be determined by the packaging technology with an electrical connection, rather than the performance of the semiconductor itself.

In examples, glass substrates may be applied as a high-end packaging substrate. By forming a through via on a glass substrate and applying a conductive material into the through via, the length of a conductive line between an element and a motherboard may be shortened, and excellent electric characteristics may be achieved.

The implementation of a strict cleaning process is indispensable a minute through via is formed on a glass substrate, and when a connection of a rewiring layer is implemented. Impurities such as dust may be extremely critical particularly when a fine line is applied.

### SUMMARY

This Summary is provided to introduce a selection of concepts in a simplified form that is further described below in the Detailed Description. This Summary is not intended to identify key features or essential features of the claimed subject matter, nor is it intended to be used as an aid in determining the scope of the claimed subject matter.

In a general aspect, a cleaned packaging substrate manufacturing method includes disposing, in a preparing process, a target substrate inside a chamber; and jetting, in a removing process, ionized air on at least one surface of the target substrate to separate particle impurities, and obtain a cleaned packaging substrate, wherein the target substrate is at least one of a glass packaging substrate; and a packaging substrate, and wherein the packaging substrate comprises the glass packaging substrate and a redistribution layer disposed on at least one surface of the glass packaging substrate.

The removing process may be configured to inhibit the occurrence of static electricity by ionized air by irradiating soft X-rays to the target substrate.

An atmosphere of a chamber in the removing process may have a flow of air which is applied with a force in a direction opposite to a direction of gravity.

The ionized air that is jetted in the removing process may be one of an inert gas and dry air.

The residual electrification potential of the substrate in the removing process may be 0 V.

A space inside the chamber in the removing process may be maintained at a low-pressure atmosphere of 0.9 atmospheric pressure or less.

The jetting of the ionized air in the removing process may be performed on one of a first surface of the substrate and a second surface of the substrate, and the air may flow at an angle of 30 degrees to 150 degrees based on the first surface of the substrate.

The glass packaging substrate may include a through via that penetrates in a thickness direction thereof, and the through via may have an opening with a maximum length of 300 μm or less.

The redistribution layer of the packaging substrate may include a blind via, and the blind via may include an opening with a maximum length of 20 μm or less.

Other features and aspects will be apparent from the following detailed description, the drawings, and the claims.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known, after an understanding of the disclosure of this application, may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween. Likewise, expressions, for example, “between” and “immediately between” and “adjacent to” and “immediately adjacent to” may also be construed as described in the foregoing.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof. The use of the term “may” herein with respect to an example or embodiment (for example, as to what an example or embodiment may include or implement) means that at least one example or embodiment exists where such a feature is included or implemented, while all examples are not limited thereto.

Unless otherwise defined, all terms, including technical and scientific terms, used herein have the same meaning as commonly understood by one of ordinary skill in the art to which this disclosure pertains consistent with and after an understanding of the present disclosure. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

In this application, the description of “A and/or B” means “A, B, or A and B.”

In this application, terms such as “first,” “second,” “A,” or “B” are used to distinguish the same terms from each other unless specially stated otherwise.

One or more examples provide a cleaned packaging substrate manufacturing method and a cleaned packaging substrate.

In one or more examples, a cleaned packaging substrate manufacturing method and a cleaned packaging substrate may minimize the damage of a substrate which may occur due to the influence of static electricity in a cleaning process and may remove impurities from a substrate having a complicated structure or small holes efficiently.

In the one or more examples, a singular form is contextually interpreted as including a plural form as well as a singular form unless specially stated otherwise.

A packaging substrate which packages elements with high performance may be desirous of regulation of the difference of a wiring scale between a board in a lower end of the substrate and elements of an upper end of the substrate. To achieve this, a process of applying a prepreg of double layers or more, a process of applying a prepreg and a silicon substrate to be double layers, or the like was applied. This is because the difference of a wiring scale between a board disposed on a lower end of the packaging substrate and element disposed on an upper end of the packaging substrate can be comparatively easily regulated through a substrate of double layers. However, the approach in this manner may be difficult to satisfy the demands of semiconductor element packaging for making a thinner film.

A packaging substrate of high-performance semiconductor elements may apply a glass substrate of one layer as a supporting layer. To that extent, it may be desirous that lines or vias having various sizes be arranged inside one packaging substrate. In order to enable the applying of a redistribution layer as a fine layer, the reducing of the size of a via, and the embodying of a complicated wiring pattern within a small area of a packaging substrate, precise control of impurities may be desired. Thus, the importance of a cleaning process is being increased in a manufacturing process of a packaging substrate.

A glass substrate may be applied as a core of a packaging substrate. When a glass substrate for semiconductor packaging whose stress is controlled is applied, a fine line with a thinner thickness can be embodied. However, a glass substrate is vulnerable to impact forces or imbalanced stress, and may be strengthened when implemented with a prepreg which is manufactured by impregnating a polymer to a glass fiber. Accordingly, when an imbalance of energy occurs inside a glass substrate, the substrate itself may be broken, and this may lead to the hassle of cleaning the entire process chamber.

Thus, a cleaning method should be applied to remove impurities efficiently while minimizing the occurrence of imbalanced stress and the occurrence of impact in a glass substrate or a packaging substrate applying the glass substrate as a core.

Hereinafter, embodiments will be described in detail.

A manufacturing method for a cleaned packaging substrate is applied to a manufacturing process for a glass substrate or a packaging substrate comprising the same, and comprises a preparing process and a removing process.

The preparing process is a process of disposing a target substrate inside a chamber.

The disposing of the target substrate means fixing the target substrate in a predetermined position so that it cannot be separated due to interaction with elements such as, but not limited to, air jets or the like.

The fixing process may dispose a target substrate in a rack equipped inside the chamber. The fixing process may dispose a target substrate in a rack of multilayers equipped inside the chamber.

The removing process is a process of jetting ionized air on at least one surface of the target substrate to separate particle impurities thereby manufacturing a cleaned substrate for packaging.

The target substrate is a glass substrate for packaging or a substrate for packaging.

The glass packaging substrate may be a glass substrate for a semiconductor, and, as only examples, may be a borosilicate glass substrate, a non-alkali glass substrate, or the like.

The glass packaging substrate may comprise a through via that penetrates in a thickness direction thereof. The through via may comprise an opening with a maximum length of approximately 300 μm or less. The through via may have an aspect ratio of approximately to approximately 1.5 which is a ratio of the maximum length of an opening compared to the height of a through via (corresponding to the thickness of a glass substrate).

When the through via has a narrow opening or a large aspect ratio, it may be beneficial to apply a more careful removing process to enable sufficient cleaning even for the inside of a via.

The glass substrate may comprise a cavity that is caved in some or the whole thereof in a thickness direction thereof.

The removing process may enable sufficient removing of impurities in not only the surface of a glass substrate, but also the inside of a via, the side plane and the base plane of a cavity, and the like.

The packaging substrate comprises the glass packaging substrate and a redistribution layer disposed on at least one surface of the glass substrate for packaging.

The redistribution layer may be disposed on one surface of the glass packaging substrate.

The redistribution layer may be respectively disposed on a first surface and a second surface of the glass packaging substrate.

The redistribution layer of the packaging substrate may comprise a blind via.

The blind via may comprise an opening with the maximum length of approximately 20 μm or less, or approximately 12 μm or less.

The redistribution layer disposed on a first surface of the glass packaging substrate may be connected to a second surface of the glass packaging substrate through a core of the glass substrate. The second surface may be connected to an external element through a buff or similar device. The second surface may also be connected to an external element through a redistribution line, a buff, or similar device disposed on the second surface.

The redistribution layer may comprise an electrically conductive layer as a fine layer. The fine layer refers to an electrically conductive layer whose width is less than approximately 4 μm. Specifically, it may be an electrically conductive layer whose width and interval are applied to be respectively less than approximately 4 μm, or approximately 1 μm to approximately 4 μm.

The thickness of the target substrate may be approximately 1,500 μm or less, approximately 300 μm to approximately 1,200 μm, 350 μm to 900 μm, or 350 μm to 700 μm.

The formation of a redistribution layer may be implemented as a multi process operation which repeats the forming of an insulating layer, the forming of a via, plating, etching, and the like. Respective processes such as forming a via, forming an insulating layer, subsequent flattening, plating, and removing unnecessary impurities after etching may benefit from a proceeding cleaning process.

In such a process, when the process proceeds in a state of being impregnated with impurities such as dust even in some portions thereof, defects such as a bridge defect, an open defect, an etch defect and the like may occur. To prevent this, impurities may be sufficiently removed, and the removing process may be applied various kinds of morphology of the surface of a complicated substrate and of materials of the surface of a substrate.

Particularly, the packaging glass substrate is a material having properties of an insulator, and the damage such as broken or shattered glass may occur. Therefore, the inside of a chamber may have to be cleaned. Additionally, damage may occur to the glass substrate itself. Furthermore, when imbalance of electric charge inside a piece of glass substrate occurs at a certain level or more, the glass substrate itself may be broken. Therefore, not only control of impact in processes, but also control of ions and static electricity in a cleaning process is desired.

The removing process jets ionized air to the target substrate and separates particle impurities.

The jetting of air may proceed through a nozzle.

The jetted air may be applied by a method of jetting ionized air, or may be treated to be ionized at the surface of a substrate after jetting air.

The jetted air may be an inert gas or dry air.

The inert gas may be nitrogen gas, argon gas, or the like, but is not limited thereto.

The jetting of air in the removing process may be made on a first surface of the substrate or a second surface of the substrate.

The air may flow at an angle of approximately 30 degrees to approximately 150 degrees based on the first surface of the substrate. The air may flow at an angle of approximately 30 degrees to approximately 85 degrees, or may flow at approximately 95 degrees to approximately 150 degrees. The inflow angle of air may be estimated through an angle of a nozzle.

In the removal of impurities in the surface of a substrate, separating the impurities from the surface by air is important. Additionally, the controlling of the separated impurities so that the separated impurities are not attached to the surface of the substrate again is also important.

Imbalance of static electricity or electric charge may occur in the surface of a target substrate due to jetting of air, and this has a tendency to be more severe when the target substrate is an insulator.

It may also be possible to remove impurities efficiently in addition to inhibiting the occurrence of static electricity and substantially not damaging a substrate, by applying methods of controlling the flow of air inside a chamber and/or irradiating UV by jetting ionized air.

The control of the flow of air inside a chamber refers to the forming of a flow of air applied with a force in a direction opposite to gravity. Preferably, the turbulence may be formed partially. When the turbulence is applied as a flow of air inside a chamber, impurities separated by jetted air may be moved inside the chamber based on the turbulence flow in order to be efficiently removed, and the impurities may be inhibited from being reattached to the substrate.

The space inside the chamber in the removing process may be maintained to be a low-pressure atmosphere of 0.9 atmospheric pressure or less.

The removing process may proceed while irradiating soft x-rays to the target substrate and inhibiting the occurrence of static electricity.

Various methods are applicable as a method for inhibiting static electricity.

Soft x-ray, electromagnetic ionizer, UV lamp, atmospheric pressure plasma, or the like may be usable as the method. The one or more examples may apply a soft x-ray as the method.

Inhibition of static electricity by implementing soft x-rays may form ions or electrons by electrolytic dissociation of air molecules around a target substrate, and may control static electricity of the surface of a target substrate. Because a light irradiation method may be applied, it has an advantage in that an additional device for transmitting ions, such as a plasma method, may not be necessary. Additionally, although irradiated in an atmosphere comprising oxygen, ozone may not be generated in substantial amounts, so that it is more advantageous for applying a UV lamp.

The soft x-ray may apply a light having a wavelength of approximately 1 angstrom to approximately t 700 angstroms, or approximately 1 angstrom to approximately 10 angstroms. Additionally, energy of electrolytic dissociation may be applied to be approximately 10 keV or less, or approximately 1 keV to approximately 10 keV. The soft x-ray may be irradiated in a distance within approximately 50 cm, or approximately 2 cm to approximately 30 cm from a target substrate. In such an example, control of static electricity may be more effectively applied.

The removing process may have a residual electrification potential which is substantially approximately 0 V. In this example, impurities may be inhibited from being reattached by static electricity, and damage of a substrate which is generated by ionization or static electricity stably may be prevented.

The manufacturing method for a cleaned packaging substrate may not substantially show damage or deformation of a substrate itself, and can remove impurities from a target substrate with high reliability. Additionally, the method can be applicable to a glass substrate as a high insulator stably and efficiently.

In another embodiment, a manufacturing method for a packaging substrate may comprise an operation of preparing a glass substrate; an operation of forming an electrically conductive layer on the substrate; an operation of forming an insulating layer; an operation of forming a conductive layer; a cleaning operation; and a testing operation.

An operation that prepares a glass substrate is an operation of preparing a glass substrate applied for semiconductor packaging. This glass substrate is a thin plate, and may comprise a cavity and/or a via as needed. The cavity refers to some of the glass substrate which is concaved, and the concaved portion may penetrate the glass substrate, or may not penetrate the glass substrate and some portions thereof may remain.

An operation of preparing a glass substrate prepares a glass substrate, which is cleaned or a glass substrate from which the static electricity has been removed. Before proceeding with subsequent operations, an additional process of cleaning or removing static electricity may further performed.

In an example, the cleaning operation may be the removing process described above, the removal of static electricity may be, for example, an operation utilizing soft x-rays described above, and these operations may be applied at the same time or in order.

An operation that forms an electrically conductive layer on the substrate is an operation that forms an electrically conductive layer in a predetermined pattern on the surface of the glass substrate.

The glass substrate may have a via or a cavity, and an electrically conductive layer may be formed in the inside of a via and the wall of a cavity.

The formation of the electrically conductive layer may proceed for example, as a method of forming a copper layer or a copper alloy layer through plating, sputtering, or the like. For example, a primer layer may be formed in a predetermined position, an insulating layer or the like may be formed, and after that a portion that forms an electrically conductive layer is partially removed to perform copper plating, thereby forming an electrically conductive layer in desired form and thickness. Depending on need, flattening of a copper plating layer may proceed.

An operation that forms an insulating layer is an operation that forms an insulating layer to be interposed between electrically conductive layers, and may be performed by curing a polymer resin containing nano particles. The insulating layer may preferably have a flattened surface (an upper surface).

An operation that forms a conductive layer is an operation that forms an electrically conductive layer in a predetermined position on the insulating layer. The formation of the electrically conductive layer may proceed for example, as a method of forming a copper layer or a copper alloy layer through plating, sputtering, and the like. For example, a primer layer may be formed in a predetermined position, an insulating layer or the like may be formed, and after that a portion that forms an electrically conductive layer is partially removed to perform copper plating, thereby forming an electrically conductive layer in desired form and thickness. Depending on need, flattening of a copper plating layer may be performed.

A cleaning operation is the cleaning operation described above, and may involve the removal of dust and/or static electricity through the flow of air.

A testing operation is an operation that checks whether or not defects are present in a substrate or a conductive line, and whether impurities that may occur in processes are clearly removed. The process may proceed through a professional testing device, and a packaging substrate which is evaluated as not passing the test based on the testing operation of the testing device may pass the cleaning operation repetitively or may be disused.

An operation that forms a via and a cleaning operation may be selectively further comprised between an operation that forms an insulating layer and an operation that forms a conductive layer.

An operation that forms a via, an operation that forms a via conductive layer and a cleaning operation may be selectively further comprised between an operation that forms an insulating layer and an operation that forms a conductive layer.

An operation that forms a via, a cleaning operation, an operation that forms a via conductive layer and a cleaning operation may be selectively further comprised between an operation that forms an insulating layer and an operation that forms a conductive layer.

In an operation that forms a via, a via may be formed in order to connect conductive layers disposed to be up and down from each other. For example, the via may be formed by performing etching of an insulating layer partially in a predetermined position and a predetermined size. For example, laser etching, plasma etching, or the like may be applied as the etching. After the etching, an operation of removing the residual of etching and an operation of confirming whether the residual of etching is removed may be selectively further comprised.

An operation that forms a via conductive layer is an operation that forms a conductive layer to the via. The conductive layer may be formed along the surface of the inner diameter of the via in a relatively regular thickness. The conductive layer may be formed in a in a manner that fills all the via. The formation of the conductive layer is similar to the process of forming an electrically conductive layer described in the above, and thus the further description is omitted.

The operation that forms the insulating layer and the operation that forms the conductive layer may proceed repetitively several times as needed. Additionally, the operations added between the operation that forms the insulating layer and the operation that forms the conductive layer may proceed repetitively several times as needed.

Descriptions of respective operations are overlapped with the above descriptions and thus the further description is omitted.

In an example, the glass substrate may be a glass substrate having a cavity structure.

An operation that disposes an element (refer to a cavity element in a meaning of being disposed inside a cavity) to a cavity or the like may be selectively further comprised between an operation that forms an electrically conductive layer on the substrate and an operation that forms an insulating layer.

The cavity element may be a capacitor such as MLCC, but is not limited thereto.

An operation of disposing an element to a cavity or the like may comprise a process of disposing a cavity element in a predetermined position, and a process of forming an insulating layer, a conductive layer, an insulating layer, and the like in predetermined positions.

Before or after the testing operation, an operation that attaches a solder ball may be further included.

The operation that attaches a solder ball is an operation that attaches a solder ball on an upper surface and/or a lower surface of the substrate.

The solder ball may directly connect the packaging substrate and external elements, and may proceed as below processes.

A process of preparing a pad in a position where a solder ball is formed, a process of forming an insulating film on one surface of the substrate by opening the upper surface of the pad, and an operation of preparing a metal masking layer in an upper surface of the pad and placing a buff and a metal ball therein may be applied in order.

The pad may be for example, aluminum but not be limited thereto. The metal masking layer may be for example, layers such as a copper alloy layer and a titanium layer formed to be one layer or more, but not be limited thereto. The metal ball may be for example, a tin ball, but not be limited thereto.

A manufacturing method for a packaging substrate can remove impurities from a target substrate with high reliability in addition to showing no substantial damage or deformation to the substrate itself. Additionally, it may be also applicable to a glass substrate as a high insulator or the like stably and efficiently.

A packaging substrate in accordance with one or more examples, may be cleaned by the method described above. The cleaned packaging substrate may inhibit bridge defects, open defects, etch defects, and the like efficiently, and may provide a packaging substrate whose reliability is improved.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. A cleaned packaging substrate manufacturing method, the method comprising:
disposing, in a preparing process, a target substrate inside a chamber; and
jetting, in a removing process, ionized air on at least one surface of the target substrate to separate particle impurities, and obtain a cleaned packaging substrate,
wherein the target substrate is at least one of a glass packaging substrate; and a packaging substrate, and
wherein the packaging substrate comprises the glass packaging substrate and a redistribution layer disposed on at least one surface of the glass packaging substrate.

2. The method of claim 1, wherein the removing process is configured to inhibit the occurrence of static electricity by ionized air by irradiating soft X-rays to the target substrate.

3. The method of claim 1, wherein an atmosphere of a chamber in the removing process has a flow of air which is applied with a force in a direction opposite to a direction of gravity.

4. The method claim 1, wherein the ionized air that is jetted in the removing process is one of an inert gas and dry air.

5. The method of claim 1, wherein the residual electrification potential of the substrate in the removing process is 0 V.

6. The method of claim 1, wherein a space inside the chamber in the removing process is maintained at a low-pressure atmosphere of 0.9 atmospheric pressure or less.

7. The method of claim 1,
wherein the jetting of the ionized air in the removing process is performed on one of a first surface of the substrate and a second surface of the substrate, and
wherein the air flows at an angle of 30 degrees to 150 degrees based on the first surface of the substrate.

8. The method of claim 1,
wherein the glass packaging substrate comprises a through via that penetrates in a thickness direction thereof, and
wherein the through via has an opening with a maximum length of 300 μm or less.

9. The method of claim 1,
wherein the redistribution layer of the packaging substrate comprises a blind via, and
wherein the blind via comprises an opening with a maximum length of 20 μm or less.

10. A packaging substrate manufactured by the manufacturing method for a cleaned packaging substrate according to claim 1.
